(19) United States
(12) Patent Application Publication
(10) Pub. No.: US 2004/0212380 A1
(43) Pub. Date: Oct. 28, 2004

(54) Failure analyzer

(75) Inventors: Tohru Koyama, Tokyo (JP); Junko Komori, Tokyo (JP)

Correspondence Address: MCDERMOTT, WILL & EMERY, 600 13th Street, N.W., WASHINGTON, DC, 20005-3096, US

(73) Assignee: RENESAS TECHNOLOGY CORP.

(21) Appl. No.: 10/830,090

(22) Filed: Apr. 23, 2004

(30) Foreign Application Priority Data
Apr. 25, 2003 (JP) JP2003-121282

(51) Int. Cl. G21K 5/10; G01R 31/308

(52) U.S. Cl. 324/754; 324/753

(57) ABSTRACT

A sample (1) is mounted on a stage (11) with an analysis plate (2) interposed therebetween. A recess (2c) is provided in a main surface (2b) of the analysis plate (2), and a protrusion (2d) functioning as a solid immersion lens is provided on a bottom surface (2ca) of the recess (2c). The protrusion (2d) does not protrude from the main surface (2b) of the analysis plate (2). Because of provision of the analysis plate (2) which includes a solid immersion lens and is separate from the sample (1), an analysis range can be changed. Further, since the protrusion (2d) does not protrude from the main surface (2b) of the analysis plate (2), the sample (1) can be stably mounted on the stage (11) with the analysis plate (2) interposed therebetween.

### BACKGROUND OF THE INVENTION

1. Field of the Invention

The present invention relates to a failure analyzer utilizing a solid immersion lens.

2. Description of the Background Art

Ever-increasing use of a multilayer structure for interconnection of a semiconductor device such as an LSI causes difficulties in evaluating or analyzing the semiconductor device from a direction of a top surface of a semiconductor substrate, so that evaluation or analysis of the semiconductor device must be carried out from a direction of a back surface of the semiconductor substrate. Typical techniques for analyzing a failure from a direction of a back surface include: emission analysis in which a failures is analyzed by detecting a feeble light emitted from a spot of current leakage; an OBIC (optical beam induced current) analysis or OBIRCH (optical beam induced resistance change) analysis in which a failure site is specified by converting a current or change in power supply current which is induced by irradiation of a laser beam into an image; and laser voltage probing (LVP) analysis in which an intensity or phase change of a reflected light provided by irradiation of a laser beam is monitored to observe a waveform of a potential at an arbitrary point. In each of the above-cited techniques for analyzing a failure from a direction of a back surface of a semiconductor substrate (which will hereinafter be referred to as “back surface analysis”), an infrared light which can be transmitted through silicon is generally employed because there is a need of accessing a semiconductor device formed on a top surface of the semiconductor substrate via the semiconductor substrate with a thickness of several hundred microns. However, because of the wavelength of the infrared light employed in back surface analysis which is equal to 1 μm or larger, an effective spatial resolution is equal to 0.7 μm or higher. As such, there is no choice but to sacrifice improvement in an image resolution to carry out back surface analysis.

In view of this, utilization of a solid immersion lens (which will be hereinafter also referred to as an “SIL”) made of silicon is proposed, as one method for improving a spatial resolution, in S. B. Ippolito et al., “High spatial resolution subsurface microscopy”, Applied Physics Letters, Vol. 78, No. 26, June 2001, pp. 4071-4073 (which will be hereinafter referred to as “Ippolito reference”). The method proposed in Ippolito reference is to increase a refractive index of a medium of a light, to obtain a resolution which overcomes a diffraction limit defined by a wavelength of the light.

More specifically, according to the method of Ippolito reference, a substantially hemispherical SIL is provided in close contact with a back surface of a semiconductor substrate, and a light transmitted through silicon is caused to be incident upon the semiconductor substrate via the SIL. As a result, a converging angle can be significantly increased as compared to a case where no SIL is provided. The resolution (d) is represented by an equation, “d=λ/(2·n·sin θ” where “n·sin θ” represents a numerical aperture NA. Ideally, the numerical aperture NA can be increased to a square of the refractive index (n) by virtue of provision of the SIL. Additionally, “θ” and “λ” in the above equation represent a half angle of the converging angle and the wavelength of the light, respectively.

Nevertheless, the method of Ippolito reference has a disadvantage that a resolution is occasionally reduced considerably due to possible creation of a clearance between the semiconductor substrate and the SIL. In order to remove this disadvantage, Japanese Patent Application Laid-Open No. 2002-189000 (which will hereinafter be referred to as “JP 2002-189000”) proposes forming of a substantially hemispherical protrusion on a surface of a semiconductor substrate by performing some processes on the surface of the semiconductor substrate, and utilizing the formed protrusion as an SIL. In other words, JP 2002-189000 describes a method in which an SIL and a semiconductor substrate are formed integrally with each other.

The method described in JP 2002-189000, in which the protrusion functioning as an SIL and the semiconductor substrate are formed integrally with each other, prevents creation of a clearance between the SIL and the semiconductor substrate. Accordingly, the method of JP 2002-189000 allows for improvement in resolution as compared to the method of Ippolito reference.

It is additionally noted that utilization of an SIL for back surface analysis of a semiconductor device is described also in Terada, “Effectiveness of solid immersion lens”, written materials for a lecture of the fourteenth semiconductor workshop sponsored by Hamamatsu Photonics K. K., and Yoshida et al., “High Resolution Laser Voltage Probing”, Proc of LSI testing symposium, 2002, pp. 143-148.

In general, in carrying out back surface analysis of a semiconductor wafer or a semiconductor chip which is cut out from a semiconductor wafer and not yet packaged, a sample (semiconductor wafer or semiconductor chip) is mounted on a stage transmitting a light with a back surface of the sample being situated downward relative to a top surface of the sample. Then, a probe is brought into contact with an electrode pad provided in the top surface of the sample to place the sample in a conducting state, and subsequently, a light is detected from, or irradiated onto, the back surface of the sample via the stage.

In this regard, the method described in Ippolito reference has a further disadvantage of having difficulties in stably mounting the sample on the stage because of inclusion of the substantially hemispherical SIL on the back surface of the semiconductor substrate which protrudes from the back surface of the semiconductor substrate.

On the other hand, in the method of JP 2002-189000, the SIL is formed by digging in the semiconductor substrate and making the back surface thereof locally spherical. As such, the SIL does not protrude from the back surface of the semiconductor substrate in JP 2002-189000, unlike Ippolito reference. Accordingly, it is possible to stably mount the sample on the stage. Nevertheless, the protrusion functioning as an SIL in JP2002-18900, which is formed by performing some processes on the semiconductor substrate itself, cannot be moved. Thus, it is impossible to change a range within which analysis can be carried out (analysis range).

### SUMMARY OF THE INVENTION

It is an object of the present invention to provide a technique for analyzing a failure which is capable of stably mounting a sample on a stage and changing an analysis range.

According to a first aspect of the present invention, a failure analyzer includes an analysis plate and a failure detector. The analysis plate includes a first main surface mounting a sample thereon and a second main surface opposite to the first main surface. The failure detector includes an optical system and detects a failure caused in the sample using the optical system. A recess is provided in the second main surface of the analysis plate. A protrusion which functions as a solid immersion lens and does not protrude from the second main surface is provided on a bottom surface of the recess. The failure detector irradiates a light onto the sample through the protrusion from a direction of the second main surface of the analysis plate, or detects a light which is emitted from the sample and penetrates through the protrusion.

Because of inclusion of the analysis plate which includes the protrusion functioning as a solid immersion lens and is separate from the sample, it is possible to move the protrusion relative to a failure site in a device layer where a device is to be formed in the sample. Accordingly, an analysis range can be changed, and failure analysis of an arbitrary portion can be easily carried out. Further, since the protrusion functioning as a solid immersion lens does not protrude from the second main surface of the analysis plate, it is possible to stably mount the sample on a stage with the analysis plate interposed therebetween.

According to a second aspect of the present invention, a failure analyzer includes a solid immersion lens, a stage and a failure detector. The stage includes a first main surface and a second main surface opposite to the first main surface. The solid immersion lens is embedded in the stage. The failure detector includes an optical system and detects a failure caused in a sample using the optical system. A portion of a surface of the solid immersion lens is flat and is exposed to be flush with the first main surface of the stage. The sample is mounted so as to extend over the first main surface of the stage and the portion of the surface of the solid immersion lens. The failure detector irradiates a light onto the sample through the stage and the solid immersion lens from a direction of the second main surface of the stage, or detects a light which is emitted from the sample and penetrates through the solid immersion lens and the stage.

Since the solid immersion lens is embedded in the stage, it is possible to move the solid immersion lens relative to a device layer where a device is to be formed in the sample. Accordingly, an analysis range can be changed, and failure analysis of an arbitrary portion can be easily carried out. Further, since the surface of the solid immersion lens includes the portion which is flat and is exposed to be flush with the first main surface of the stage, it is possible to stably mount the sample on the stage and the solid immersion lens.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 and 2 illustrate a structure of a failure analyzer according to a first preferred embodiment of the present invention.

FIG. 3 is a plan view of a sample 1 which is a target of analysis.

FIG. 4 is a plan view of an analysis plate according to the first preferred embodiment of the present invention.

FIG. 5 illustrates the structure of the failure analyzer according to the first preferred embodiment of the present invention.

FIG. 6 illustrates a structure of a failure analyzer according to a modification of the first preferred embodiment of the present invention.

FIGS. 7, 8 and 9 illustrate a structure of a failure analyzer according to a second preferred embodiment of the present invention.

FIGS. 10 through 13 illustrate a structure of a failure analyzer according to a third preferred embodiment of the present invention.

FIG. 14 is a plan view of an analysis plate according to a fourth preferred embodiment of the present invention.

FIG. 15 is a plan view of a stage according to the fourth preferred embodiment of the present invention.

FIGS. 16, 17 and 18 illustrate a structure of a failure analyzer according to a fifth preferred embodiment of the present invention.

FIG. 19 illustrates a structure of a failure analyzer according to a sixth preferred embodiment of the present invention.

FIG. 20 illustrates a structure of a failure analyzer according to a seventh preferred embodiment of the present invention.

### DESCRIPTION OF THE PREFERRED EMBODIMENTS

Preferred Embodiments

First Preferred Embodiment

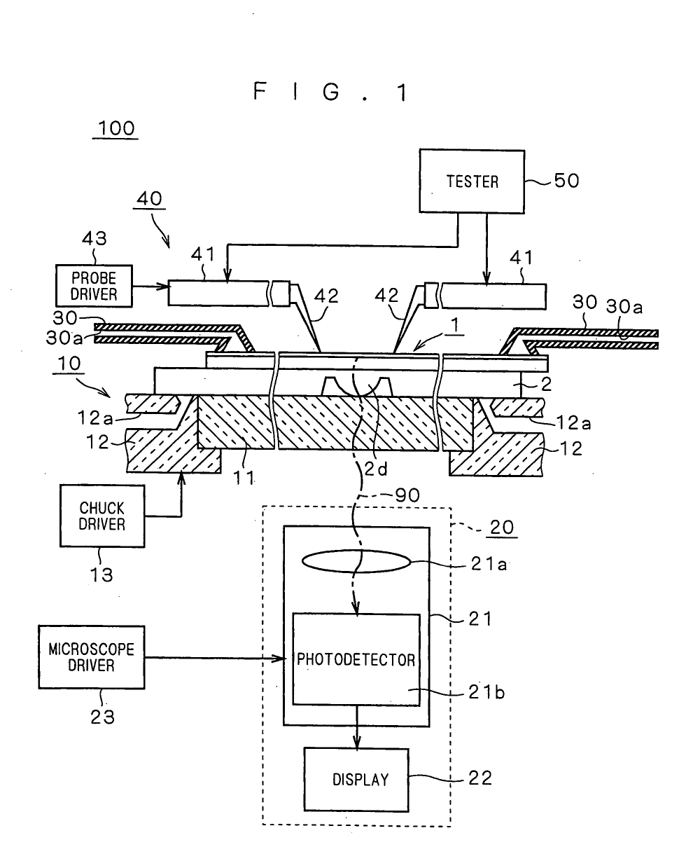

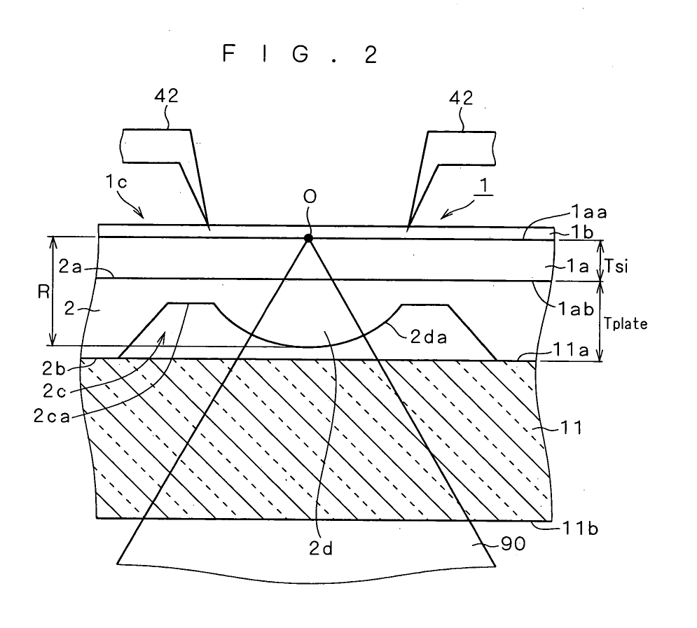

FIG. 1 illustrates a structure of a failure analyzer 100 according to a first preferred embodiment of the present invention. FIG. 2 is a magnified view of a portion of the structure illustrated in FIG. 1. As illustrated in FIGS. 1 and 2, the failure analyzer 100 according to the first preferred embodiment is capable of carrying out emission analysis on a sample 1. The failure analyzer 100 according to the first preferred embodiment includes an analysis plate 2 including an SIL, an SIL driver 10, a failure detector 20, a microscope driver 23, a sample support member 30, a prober 40 and a tester 50. It is noted that out of the elements illustrated in FIGS. 1 and 2, the sample 1, the analysis plate 2, the sample support member 30, a stage 11, a chuck 12 and a probe card 41 are illustrated in section. Additionally, details of the stage 11, the chuck 12 and the probe card 41 will be later provided.

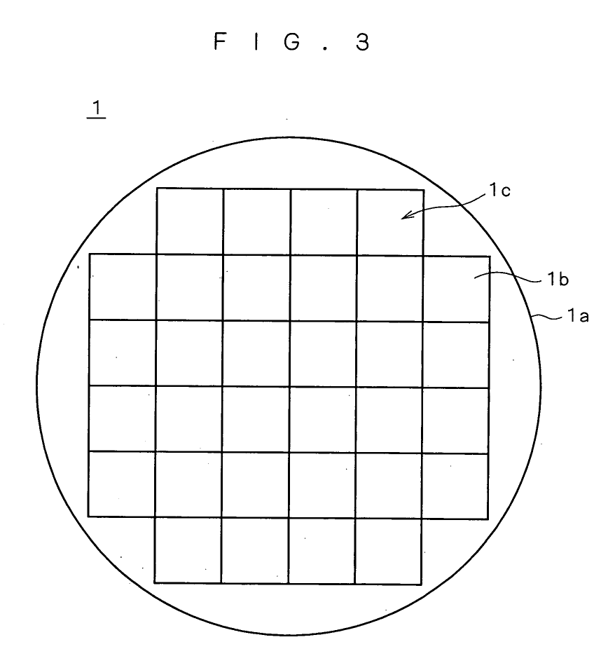

FIG. 3 is a plan view of a structure of the sample 1 which is a target of analysis carried out by the failure analyzer 100. As illustrated in FIG. 3, the sample 1 is a semiconductor wafer in which a plurality of semiconductor chips 1c are provided. The sample 1 includes a semiconductor substrate 1a and a device layer 1b where a device is to be formed. The device layer 1b is situated on a main surface 1aa which is one of opposite main surfaces of the semiconductor substrate 1a, and includes a semiconductor device such as a MOS transistor, an interlayer insulating layer, a contact plug, an interconnect line and the like which are not illustrated. The semiconductor substrate 1a is a silicon substrate, for example. It is noted that though the semiconductor wafer in which the plurality of semiconductor chips 1c are provided is employed as the sample 1 in an example described herein, each of the semiconductor chips 1c which is cut out from the semiconductor wafer can be employed alone as the sample 1.

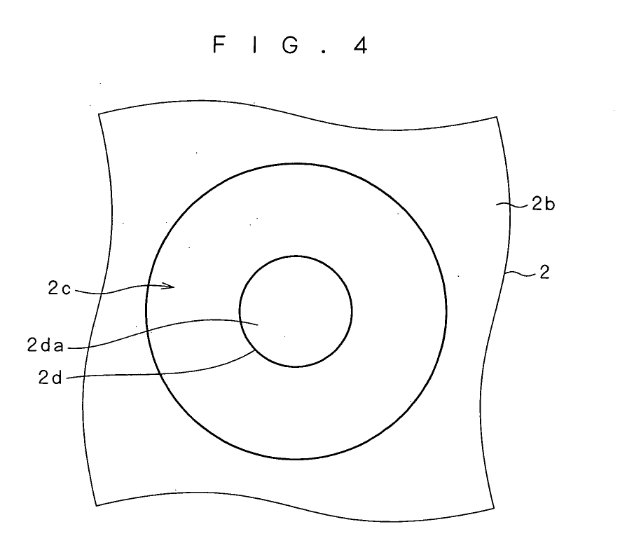

The analysis plate 2 is made of silicon, for example, and includes a main surface 2a and a main surface 2b opposite to the main surface 2a. Also, a recess 2c is provided in the main surface 2b of the analysis plate 2 as illustrated in FIGS. 1 and 2. On a bottom surface 2ca of the recess 2c, a protrusion 2d which is a spherical protrusion obtained by cutting a sphere with one plane and functions as a hemispherical SIL is formed. The protrusion 2d includes a locally spherical surface 2da. The recess 2c and the protrusion 2d are formed by digging in the analysis plate 2 from the main surface 2b, so that the recess 2c and the protrusion 2d are integral with each other. Accordingly, the protrusion 2d functioning as an SIL does not protrude from a portion of the main surface 2b where the recess 2c is not provided. FIG. 4 is a plan view of the analysis plate 2 as it is viewed from above the main surface 2b.

The sample 1 is mounted on the main surface 2a of the analysis plate 2 with a main surface 1ab of the semiconductor substrate 1a being situated closer to the analysis plate 2 than the main surface 1aa. Also, the sample 1 is mounted on the analysis plate 2 so as to come into close contact with the analysis plate 2. Since both the analysis plate 2 and the semiconductor substrate 1a of the sample 1 are made of silicon, a center O of the locally spherical surface 2da of the protrusion 2d functioning as a hemispherical SIL is located on the main surface 1aa of the semiconductor substrate 1a provided on the analysis plate 2, as illustrated in FIG. 2. Respective thicknesses Tplate and Tsi of the analysis plate 2 and the semiconductor substrate 1a are determined to satisfy the following equation (1):

Tplate+Tsi>R (1)

where “R” represents a radius of the locally spherical surface 2da of the protrusion 2d.

The SIL driver 10 includes the stage 11, the chuck 12 for supporting the stage 11 by engaging an edge portion of the stage 11, and a chuck driver 13 for moving the chuck 12. As illustrated in FIG. 2, the stage 11 includes a main surface 11a and a main surface 11b opposite to the main surface 11a. The stage 11 is made of a material transmitting a light, for example, quartz glass which is transparent. On the main surface 11a of the stage 11, the analysis plate 2 is mounted with the main surface 2b of the analysis plate 2 being situated closer to the stage 11 than the main surface 2a.

The analysis plate 2 is mounted so as to extend over also a top surface of the chuck 12 with the main surface 2b being situated downward relative to the main surface 2a. As with the stage 11, the chuck 12 is made of a material transmitting a light, for example, quartz glass which is transparent. The chuck 12 functions to fix the analysis plate 2 on the stage 11 by vacuum suction. More specifically, the chuck 12 includes an exhaust hole 12a which passes through the chuck 12 to reach a top surface of the chuck 12 and provide an opening in the top surface of the chuck 12. The analysis plate 2 is mounted on the chuck 12 so as to block the opening in the top surface of the exhaust hole 12a. With such positional relationship, to discharge an air within the exhaust hole 12a to the outside of the chuck 12 would allow the analysis plate 2 to be attracted to the chuck 12 by vacuum suction. As a result, the analysis plate 2 is fixed on the stage 11.

The chuck driver 13 is capable of moving the chuck 12 in parallel to the main surface 11a of the stage 11. Also, the chuck driver 13 is capable of moving the chuck 12 perpendicularly to the main surface 11a of the stage 11. As the chuck 12 is moved, also the stage 11 is moved in the same manner because the stage 11 is supported by the chuck 12. Further, as the chuck 12 is moved, also the analysis plate 2 is moved in the same manner because the analysis plate 2 is fixed on the stage 11. Accordingly, when the chuck driver 13 moves the chuck 12 in parallel to the main surface 11a of the stage 11, the analysis plate 2 is moved along a direction parallel to the main surface 2a of the analysis plate 2. On the other hand, when the chuck driver 13 moves the chuck 12 perpendicularly to the main surface 11a of the stage 11, the analysis plate 2 is moved along a direction perpendicular to the main surface 2a of the analysis plate 2.

As described above, it is possible to move the analysis plate 2 along the direction parallel to the main surface 2a and along the direction perpendicular to the main surface 2a by using the SIL driver 10.

The prober 40 includes the probe card 41, a probe 42 connected to the probe card 41, and a probe driver 43. The probe card 41 and the probe 42 are situated above the sample 1 mounted on the analysis plate 2. The probe driver 43 is capable of moving the probe card 41 in parallel to the main surface 2a of the analysis plate 2. Such movement of the probe card .41 makes the probe 42 movable in parallel to the main surface 2a of the analysis plate 2. Also, the probe driver 43 is capable of moving the probe card 41 perpendicularly to the main surface 2a of the analysis plate 2. Such movement of the probe card 41 makes the probe 42 movable perpendicularly to the main surface 2a of the analysis plate 2. In actually carrying out back surface analysis, the probe driver 43 moves the probe card 41, to bring the probe 42 into contact with an electrode pad (not illustrated) provided in the device layer 1b of the sample 1.

The tester 50 generates a test pattern required for failure analysis, and sends the generated test pattern to the probe card 41. The probe card 41 receives the test pattern and applies the test pattern to the sample 1 via the probe 42, to thereby supply a predetermine electrical signal to the sample 1.

The failure detector 20 includes an optical microscope 21 which includes an optical system 21a formed of an objective lens and the like and a photodetector 21b, and a display 22. The optical microscope 21 is situated below the stage 11.

The photodetector 21b of the optical microscope 21 is capable of detecting an extremely feeble light which is measured in photon, and includes a photomultiplier tube, an image sensor and the like. In operation, a light 90 emitted from a spot of current leakage in the device layer 1b of the sample 1 penetrates through the semiconductor substrate 1a, the analysis plate 2, the stage 11 and the optical system 21a, to enter the photodetector 21b.

The microscope driver 23 is capable of moving the optical microscope 21 in parallel to the main surface 2a of the analysis plate 2, and is also capable of moving the optical microscope 21 perpendicularly to the main surface 2a of the analysis plate 2.

The sample support member 30 supports the sample 1 independently of the analysis plate 2 from above the top surface thereof by vacuum suction. The sample support member 30 includes an exhaust hole 30a, and is situated on an edge portion of the top surface of the sample 1 such that one of opposite ends of the exhaust hole 30a is blocked by the sample 1. To discharge an air within the exhaust hole 30a to the outside of the sample support member 30 would allow the sample 1 to be attracted to the sample support member 30 by vacuum suction.

Out of all the elements included in the failure analyzer 100 according to the first preferred embodiment, the elements other than the chuck driver 13, the display 22, the microscope driver 23, the probe driver 43 and the tester 50 are contained in one single housing (not illustrated). The sample support member 30 is attached to the housing, so that the sample support member 30 is fixedly positioned in the housing. Accordingly, to move the analysis plate 2 or the probe 42 would not result in movement of the sample support member 30, as well as the sample 1 held by the sample support member 30.

In the meantime, the chuck driver 13, the microscope driver 23 and the probe driver 43 move the chuck 12, the optical microscope 21 and the probe card 41, respectively, based on the same x,y,z-rectangular coordinate system. The x,y,z-rectangular coordinate system is defined by an x axis and a y axis each of which extends in parallel to both the main surface 2a of the analysis plate 2 and the main surface 11a of the stage 11, for example, and a z axis extending perpendicularly to the x axis and the y axis. Respective values of an x coordinate, a y coordinate and a z coordinate in the x,y,z-rectangular coordinate system are externally specified. The chuck driver 13, the microscope driver 23 and the probe driver 43 move the chuck 12, the optical microscope 21 and the probe card 41, respectively, to positions identified by the externally specified values of the x, y, z coordinates. It is noted that the x,y,z-rectangular coordinate system used for movements of the chuck 12, the optical microscope 21 and the probe card 41 will hereinafter be referred to as an “x,y,z-rectangular coordinate system Q”.

Below, a method of carrying out emission analysis on the sample 1 using the failure analyzer 100 according to the first preferred embodiment will be described in detail.

First, the sample 1 is mounted on the analysis plate 2 fixed on the stage 11 as described above. Then, the chuck 12 is moved perpendicularly to the main surface 11 a of the stage 11 using the chuck driver 13, to bring the sample 1 and the sample support member 30 into contact with each other. As a result, the sample support member 30 is situated on the top surface of the sample 1 so that one of opposite ends of the exhaust hole 30a of the sample support member 30 is blocked by the sample 1.

Next, an air within the exhaust hole 30a is discharged out from the other of the opposite ends of the exhaust hole 30a which is not blocked by the sample 1, to draw the sample 1 to the sample support member 30 by suction force. As a result, the sample 1 is held by the sample support member 30 while being in close contact with the analysis plate 2, and the sample 1 is fixedly positioned.

Subsequently, the chuck 12 is moved in parallel to the main surface 11a of the stage 11 using the chuck driver 13, to move the analysis plate 2 along the direction parallel to the main surface 2a thereof. Then, the movement of the chuck 12 is stopped when the protrusion 2d functioning as an SIL comes to a position just below a predetermined target region for failure analysis of one of the semiconductor chips 1c.

Thereafter, the optical microscope 21 is moved in parallel to the main surface 2a of the analysis plate 2 using the microscope driver 23, to situate the optical system 21a and the photodetector 21b just below the protrusion 2d of the analysis plate 2. Further, the optical microscope 21 is moved perpendicularly to the main surface 2a of the analysis plate 2 using the microscope driver 23 such that the optical system 21a is situated at a predetermined distance from the protrusion 2d of the analysis plate 2.

After the movement of the optical microscope 21, the probe 42 is brought into contact with an electrode pad (not illustrated) provided in the one semiconductor chip 1c, using the probe driver 43. Then, a predetermined test pattern is generated in the tester 50 and is sent to the probe card 41, which in turn applies the test pattern to the sample 1 via the probe 42. As a result, a predetermined electrical signal is applied to the sample 1, to place the sample 1 in an operating mode.

With the sample 1 being placed in an operating mode, the light 90 which is emitted from a spot of current leakage in the device layer 1b of the one semiconductor chip 1c and penetrates through the protrusion 2d of the analysis plate 2 and the stage 11, is detected in the optical microscope 21. In the optical microscope 21, the light 90 is converged by the optical system 21a and converted into a photoelectron by the photomultiplier tube of the photodetector 21b. Subsequently, the photoelectron is electrically multiplied by the photomultiplier tube, to be again converted into a light, which then enters the image sensor. The image sensor outputs an emission position and an emission intensity of the light 90 to the display 22 as a detection data. The display 22 receives the detection data from the image sensor of the photodetector 21b, and displays the emission position and the emission intensity of the light 90 emitted from the spot of current leakage in the form of an image (which will hereinafter be also referred to as an “emitted light image”) on a monitor (not illustrated), based on the received detection data. At that time, also an image of a pattern of the sample 1 previously stored as data (which will hereinafter be referred to as a “pattern image”) is displayed on the monitor in the display 22. Thus, the pattern image and the emitted light image are displayed while overlapping each other.

In the foregoing manner, a failure caused in the device layer 1b is detected in the failure detector 20 using the optical system 21a. In the structure according to the first preferred embodiment, the center O of the locally spherical surface 2da of the protrusion 2d and an aplanatic point of the light 90 in the sample 1 are located at the same position as illustrated in FIG. 2. More specifically, both the center O and the aplanatic point of the light 90 are located on the main surface 1aa of the semiconductor substrate la in the structure according to the first preferred embodiment. Then, the protrusion 2d functions as a hemispherical SIL as descried above, so that the light 90 emitted from the spot of current leakage travels straightforward toward the optical system 21a without being refracted at the surface of the protrusion 2d, as illustrated in FIG. 2.

Following the detection of the failure, failure analysis of the sample 1 is initiated based on the emitted light image and the pattern image displayed on the monitor of the display 22. More specifically, a location, a type or the like of the failure is specified based on the position, brightness or the like of the emitted light image displayed on the monitor. This can lead to detection of a defect in an oxide film of the sample 1, a break in an interconnection line of the sample 1, or the like. Further, a functional failure of the sample 1 or the like caused due to current leakage can be detected also.

After the failure analysis of the predetermined target region of the one semiconductor chip 1c is finished, the probe card 41 is moved using the probe driver 43, to bring the probe 42 out of contact with the sample 1. Subsequently, the analysis plate 2 is moved along the direction parallel to the main surface 2a thereof such that the protrusion 2d is situated just below a different predetermined target region of the same semiconductor chip 1c. Then, failure analysis of the different predetermined target region of the one semiconductor chip 1c is carried out in the same manner as described above. When failure analysis of all regions of the one semiconductor chip 1c is finished, the analysis plate 2 is moved and failure analysis of another one of the semiconductor chips 1c is carried out.

As is made clear from the above description, the failure analyzer 100 according to the first preferred embodiment includes the analysis plate 2 which includes the protrusion 2d functioning as an SIL and is separate from the sample 1. The protrusion 2d can be moved relative to a target region for analysis in the device layer 1b of the sample 1. Accordingly, an analysis range can be changed, which facilitates failure analysis of an arbitrary region.

Further, since the protrusion 2d functioning as an SIL does not protrude from the main surface 2b of the analysis plate 2, it is possible to stably mount the sample 1 on the stage 11 with the analysis plate 2 interposed therebetween as described above.

Moreover, according to the first preferred embodiment, the sample 1 is held independently of the analysis plate 2 by the sample support member 30. Hence, the sample 1 is not moved even when the analysis plate 2 is moved. Therefore, it is possible to easily align the protrusion 2d functioning as an SIL with a target region for analysis.

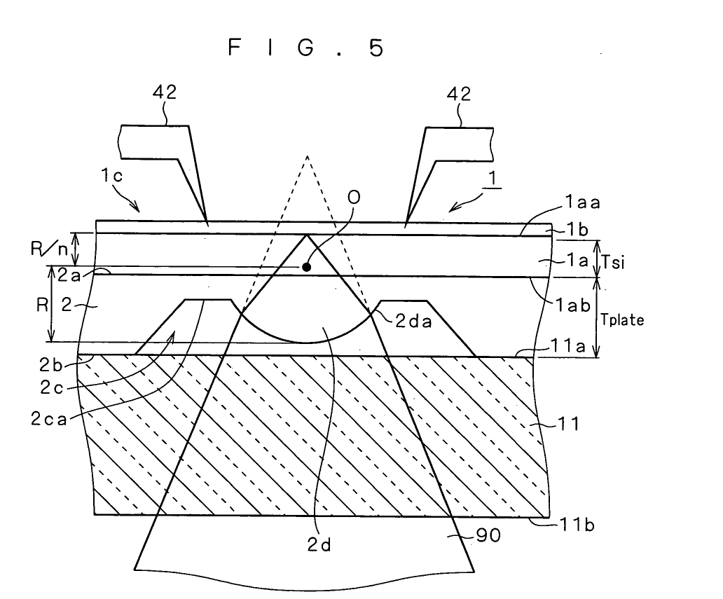

It is noted that though the protrusion 2d of the analysis plate 2 is formed so as to function as a hemispherical SIL in the above description of the first preferred embodiment, the protrusion 2d may alternatively be formed so as to function as a superspherical SIL as illustrated in FIG. 5. In a case where the protrusion 2d is formed so as to function as a superspherical SIL, the center O of the locally spherical surface 2da of the protrusion 2d is located at a position different from a position of the aplanatic point in the sample 1. Specifically, assuming that a refractive index of the semiconductor substrate 1a is “n”, the center O of the locally spherical surface 2da of the protrusion 2d is located at a distance of R/n along the thickness of the semiconductor substrate 1a from the main surface 1aa of the semiconductor substrate 1a within the semiconductor substrate 1a. On the other hand, the aplanatic point is located on the main surface 1aa of the semiconductor substrate 1a. Since the protrusion 2d functions as a superspherical SIL, the light 90 emitted from a spot of current leakage is refracted at the surface of the protrusion 2d as illustrated in FIG. 5. It is noted that in the case where the protrusion 2d is formed so as to function as a superspherical SIL, the respective thicknesses Tplate and Tsi of the analysis plate 2 and the semiconductor substrate 1a are determined to satisfy the following equation (2):

Tplate+Tsi>R(1+1/n) (2).

Furthermore, though the above description of the first preferred embodiment has been made about the failure analyzer 100 adapted to carry out emission analysis by way of example, the present invention can be applied also to a failure analyzer for carrying out OBIC analysis or OBIRCH analysis, and a failure analyzer for carrying out a laser voltage probing analysis. More specifically, OBIC analysis or OBIRCH analysis can be accomplished by irradiating a laser light onto the sample 1 through the protrusion 2d of the analysis plate 2. On the other hand, laser voltage probing analysis can be accomplished by irradiating a laser light onto the sample 1 through the protrusion 2d of the analysis plate 2 and detecting its reflected light from the sample 1 through the protrusion 2d. Below, a specific description will be made about a case where the present invention is applied to a failure analyzer for carrying out OBIC analysis as a representative example of application of the present invention to a failure analyzer which carries out failure analysis utilizing irradiation of a light onto the sample 1 through the protrusion 2d of the analysis plate 2.

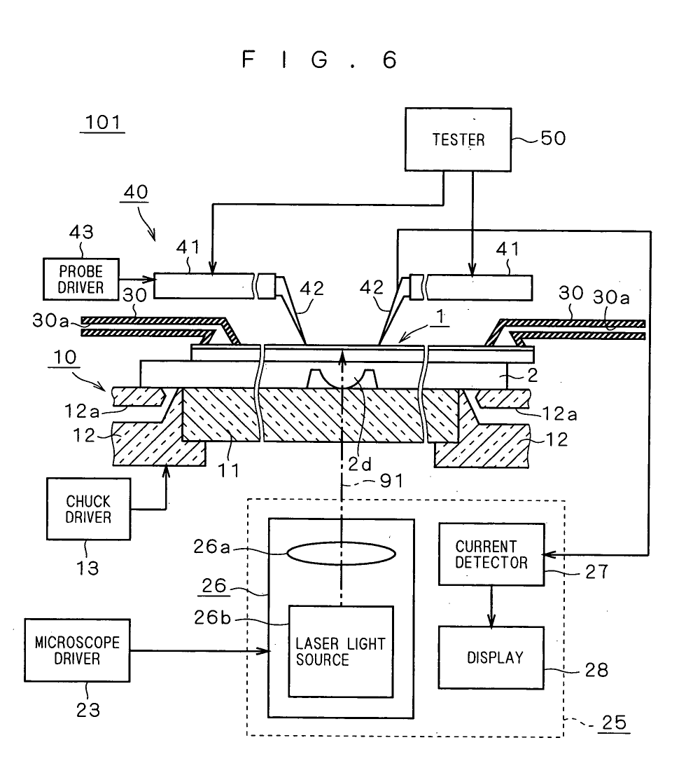

FIG. 6 illustrates a structure of a failure analyzer 101 according to a modification of the first preferred embodiment. The failure analyzer 101 is adapted to carry out OBIC analysis on the sample 1. The failure analyzer 101 is structurally different from the failure analyzer 100 illustrated in FIG. 1 in that a failure detector 25 is provided in place of the failure detector 20.

The failure detector 25 includes an optical microscope 26 including an optical system 26a formed of an objective lens and the like, and a laser light source 26b, a current detector 27 connected to the probe 42, and a display 28. The optical microscope 26 is situated below the stage 1. The microscope driver 23 is capable of moving the optical microscope 26 in parallel to the main surface 2a of the analysis plate 2 and is also capable of moving the optical microscope 26 perpendicularly to the main surface 2a of the analysis plate 2. All the other elements included in the structure of the failure analyzer 101 are identical to those of the failure analyzer 100 illustrated in FIG. 1, and thus description thereof is omitted.

Below, a method of carrying out OBIC analysis on the sample 1 using the failure analyzer 101 will be described.

First, the sample 1 is mounted on the analysis plate 2 fixed on the stage 11, and the analysis plate 2 is moved under control of the SIL driver 10 to bring the sample 1 and the sample support member 30 into contact with each other, in the same manner as in the above-described method of carrying out emission analysis. Then, the sample 1 is held by the sample support member 30, to be fixedly positioned.

Next, the analysis plate 2 is moved such that the protrusion 2d is situated just below a predetermined target region for failure analysis of one of the semiconductor chips 1c. Thereafter, the optical microscope 26 is moved using the microscope driver 23, to situate the optical system 26a and the laser light source 26b just below the protrusion 2d of the analysis plate 2. Further, the optical microscope 26 is moved perpendicularly to the main surface 2a of the analysis plate 2 using the microscope driver 23 such that the optical system 26a is situated at a predetermined distance from the protrusion 2d of the analysis plate 2.

After the movement of the optical microscope 26, the probe 42 is brought into contact with an electrode pad provided in the one semiconductor chip 1c. Then, a test pattern is generated in the tester 50 and is sent to the probe card 41, which in turn applies the test pattern to the sample 1 via the probe 42.

Subsequently, the laser light source 26b is caused to generate a laser light 91, which then enters the optical system 26a. The laser light 91 is converged by the optical system 26a and irradiated onto the device layer 1b of the sample 1, having penetrated through the stage 11 and the protrusion 2d of the analysis plate 2. Upon irradiation of the laser light 91 onto the sample 1, an optical beam induced current is generated in the device layer 1b and is supplied to the current detector 27 via the probe 42. The current detector 27 amplifies the received optical beam induced current, to convert the current into a luminance information which in turn is input to the display 28. The display 28 receives the luminance information from the current detector 27, and displays an image of the optical beam induced current (which will hereinafter be referred to as an “OBIC image”) on a monitor (not illustrated) based on the luminance information. At that time, also a pattern image of the sample 1 previously stored as data is displayed on the monitor in the display 28. Thus, the pattern image and the OBIC image are displayed while overlapping each other. In this manner, a failure caused in the device layer 1b is detected by the failure detector 25.

As is made clear from the above description, the present invention can be applied to not only failure analysis such as emission analysis which is accomplished by detecting a light emitted from the device layer 1b through the protrusion 2d, but also failure analysis such as OBIC analysis which is accomplished by irradiating a light onto the device layer 1b through the protrusion 2d. It is noted that a light which is emitted from the device layer 1b and is dealt with in emission analysis, a reflected light from the device layer 1b and is dealt with in laser voltage probing analysis, and a light which is irradiated onto the device layer 1b and is dealt with in OBIC analysis, OBIRCH analysis and laser voltage probing analysis, will hereinafter be collectively referred to as an “analysis light” in some cases.

Second Preferred Embodiment

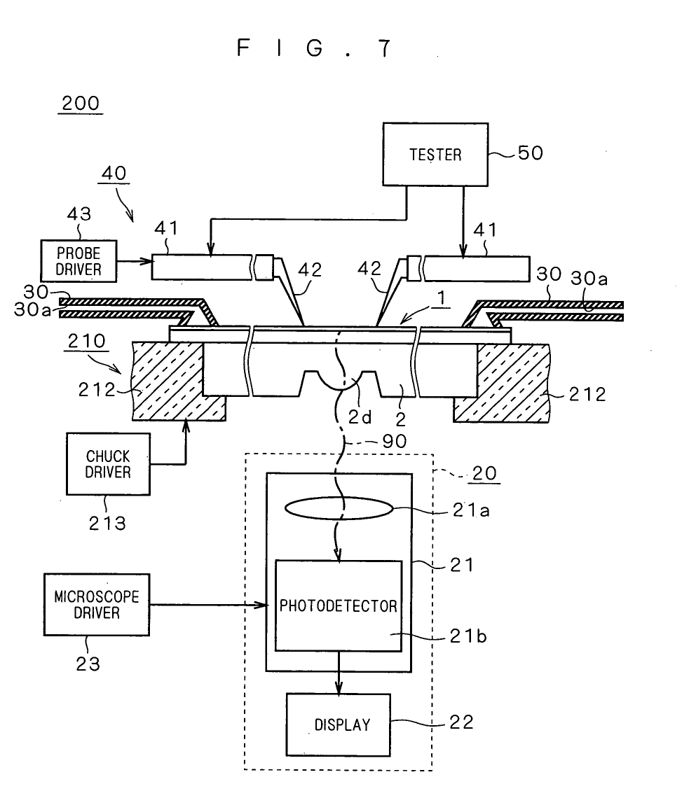

FIG. 7 illustrates a structure of a failure analyzer 200 according to a second preferred embodiment of the present invention. The failure analyzer 200 according to the second preferred embodiment is structurally different from the failure analyzer 100 according to the first preferred embodiment in that the stage 1 is removed and the analysis plate 2 is also used as a stage for mounting the sample 1, and that an SIL driver 210 is provided in place of the SIL driver 10. It is noted that out of the elements illustrated in FIG. 7, the sample 1, the analysis plate 2, the sample support member 30, the probe card 41, and a chuck 212 later described, are illustrated in section.

The analysis plate 2 according to the second preferred embodiment not only functions to increase a resolution by means of an SIL, but also is used as a stage for mounting the sample 1. As such, the analysis plate 2 according to the second preferred embodiment is required to have a higher strength than that of the analysis plate 2 according to the first preferred embodiment. For this reason, the analysis plate 2 according to the second preferred embodiment is thicker than the analysis plate 2 according to the first preferred embodiment. The SIL driver 210 includes the chuck 212 for supporting the analysis plate 2 by engaging an edge portion of the analysis plate 2, and a chuck driver 213 for moving the chuck 212. The sample 1 is mounted so as to extend over the analysis plate 2 and the chuck 212.

The chuck driver 213 is capable of moving the chuck 212 in parallel to the main surface 2a of the analysis plate 2 and perpendicular to the main surface 2a of the analysis plate 2, based on the x,y,z-rectangular coordinate system Q. Thus, the analysis plate 2 can be moved along a direction parallel to the main surface 2a thereof and along a direction perpendicular to the main surface 2a thereof, by using the SIL driver 210. All the other elements included in the failure analyzer 200 are identical to those of the failure analyzer 100 according to the first preferred embodiment, and thus description thereof is omitted.

Below, a method of carrying out emission analysis on the sample 1 using the failure analyzer 200 according to the second preferred embodiment will be described in detail.

First, the sample 1 is mounted on the main surface 2a of the analysis plate 2 supported by the chuck 212, and on the chuck 212. At that time, the sample 1 and the analysis plate 2 are brought into close contact with each other. Then, the chuck 212 is moved perpendicularly to the main surface 2a of the analysis plate 2 using the chuck driver 213, to bring the sample 1 and the sample support member 30 into contact with each other. Subsequently, the exhaust hole 30a of the sample support member 30 is evacuated, to draw the sample 1 to the sample support member 30 by suction force. As a result, the sample 1 is held by the sample support member 30 while being in close contact with the analysis plate 2, and the sample 1 is fixedly positioned.

Subsequently, the chuck 212 is moved using the chuck driver 213, to move the analysis plate 2 along the direction parallel to the main surface 2a thereof. The movement of the chuck 212 is stopped when the protrusion 2d functioning as an SIL is situated just below a predetermined target region for failure analysis of one of the semiconductor chips 1c. Thereafter, the optical microscope 21 is moved to a predetermined position using the microscope driver 23 and a test pattern generated by the tester 50 is applied to the sample 1 in the same manner as in the method described in the first preferred embodiment.

Then, the light 90 which is emitted from a spot of current leakage in the device layer 1b of the one semiconductor chip 1c and penetrates through the protrusion 2d of the analysis plate 2 is detected in the optical microscope 21. The optical microscope 21 provides a result of the detection to the display 22. The display 22 receives the result of the detection from the optical microscope 21, and displays an emission position and an emission intensity of the light 90 emitted from the spot of current leakage in the form of an image on a monitor (not illustrated), based on the result of the detection. At that time, also a pattern image of the sample 1 previously stored as data is displayed on the monitor in the display 22. Thus, the pattern image and the emitted light image are displayed while overlapping each other, and a failure caused in the device layer 1b is detected in the failure detector 20. Then, failure analysis of the sample 1 is initiated based on the emitted light image and the pattern image displayed on the monitor of the display 22.

As is made clear from the above description, in the failure analyzer 200 according to the second preferred embodiment, the analysis plate 2 including an SIL is also used as a stage for mounting the sample 1. Accordingly, there is no need of additionally providing the stage 11 separate from the analysis plate 2, unlike the failure analyzer 100 according to the first preferred embodiment. This allows for reduction of costs associated with elements included in the failure analyzer 200 while ensuring that the sample 1 is stably mounted on a stage. Further, since reflection of an analysis light at the main surfaces 11a and 11b of the stage 11 does not occur, the light can be used more efficiently in back surface analysis.

It is noted that though the above description of the second preferred embodiment has been made assuming that the analysis plate 2 is made of silicon, the analysis plate 2 may alternatively be made of quartz glass which is transparent, for example. Such alternative structure in which the analysis plate 2 is made of quartz glass is equivalent to a structure in which a protrusion functioning as an SIL is formed in the main surface 11b of the stage 11 made of quartz glass which is used in the failure analyzer 100 according to the first preferred embodiment and the stage 11 with the protrusion is used in place of the analysis plate 2 according to the second preferred embodiment.

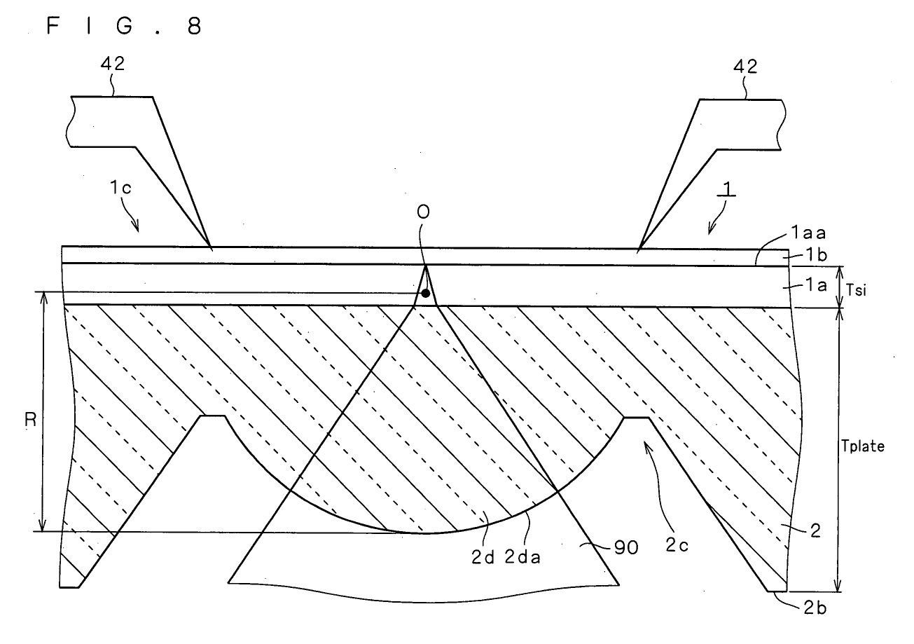

FIG. 8 is a magnified view of a portion of the alternative structure in which the analysis plate 2 according to the second preferred embodiment is made of quartz glass. It is noted that out of the elements illustrated in FIG. 8, the analysis plate 2 and the sample 1 are illustrated in section.

In the structure in which the analysis plate 2 is made of quartz glass, a material forming the analysis plate 2 is different from a material forming the semiconductor substrate 1a. For this reason, the light 90 emitted from the device layer 1b is refracted at an interface between the semiconductor substrate 1a and the analysis plate 2. Accordingly, unlike the structure in which the analysis plate 2 and the semiconductor substrate 1a are made of the same material, it is necessary to locate the center O of the locally spherical surface 2da of the protrusion 2d functioning as a hemispherical SIL at a position different from a position of an aplanatic point. For example, under conditions that the thickness Tplate of the analysis plate 2 is 2000 μm, the thickness Tsi of the semiconductor substrate 1a is 300 μm, a refractive index provided by the analysis plate 2 made of quartz glass is 1.52, and a refractive index provided by the semiconductor substrate 1a made of silicon is 3.5, the radius R of the locally spherical surface 2da of the protrusion 2d is set to 1675 μm and the center O of the locally spherical surface 2da of the protrusion 2d is located at a distance of 185 μm along the thickness of the semiconductor substrate 1a from the main surface 1aa of the semiconductor substrate 1a within the semiconductor substrate 1a.

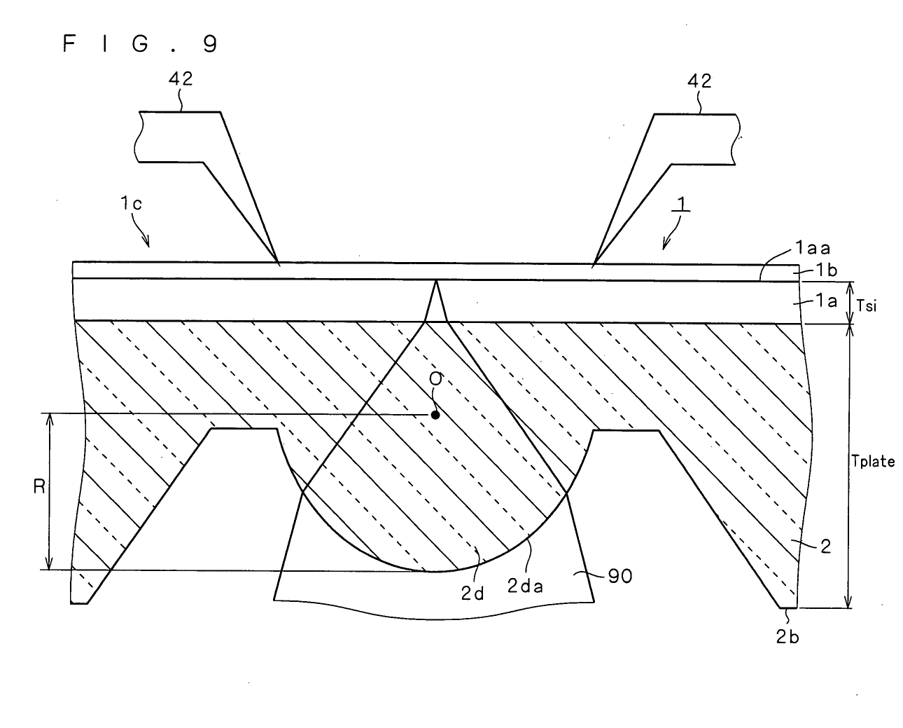

Also in a case where the protrusion 2d of the analysis plate 2 made of quartz glass is formed so as to function as a superspherical SIL, the light 90 emitted from the device layer 1b is refracted at the interface between the semiconductor substrate 1a and the analysis plate 2 as illustrated in FIG. 9. Hence, unlike the structure in which the analysis plate 2 and the semiconductor substrate 1a are made of the same material, the center O of the locally spherical surface 2da of the protrusion 2d functioning as a superspherical SIL is not located at a position which is at a distance of R/n along the thickness of the semiconductor substrate 1a from the main surface 1aa of the semiconductor substrate 1a within the semiconductor substrate 1a.

For example, under conditions that the thickness Tplate of the analysis plate 2 is 2000 μm, the thickness Tₛᵢ of the semiconductor substrate 1a is 300 μm, a refractive index provided by the analysis plate 2 made of quartz glass is 1.52, and a refractive index provided by the semiconductor substrate 1a made of silicon is 3.5, the radius R of the locally spherical surface 2da of the protrusion 2d is set to 1145 μm and the center O of the locally spherical surface 2da of the protrusion 2d is located at a distance of 930 μm along the thickness of the semiconductor substrate 1a from the main surface 1aa of the semiconductor substrate 1a within the semiconductor substrate 1a. It is additionally noted that when both the analysis plate 2 and the semiconductor substrate 1a are made of silicon and the same conditions as noted above are met, the center O of the locally spherical surface 2da of the protrusion 2d is located at a distance of 327 μm (approximately equal to 1145/3.5 μm) along the thickness of the semiconductor substrate 1a from the main surface 1aa of the semiconductor substrate 1a within the semiconductor substrate 1a.

As is made clear from the above description, when the analysis plate 2 is made of quartz glass, the analysis plate 2 provides a lower refractive index than that provided by the analysis plate 2 made of silicon. Hence, while the effects of increasing a resolution which are produced by the inclusion of an SIL may be lessened, an analysis light can be more efficiently used in back surface analysis because quartz glass transmits a light with a higher transmittance than silicon.

Third Preferred Embodiment

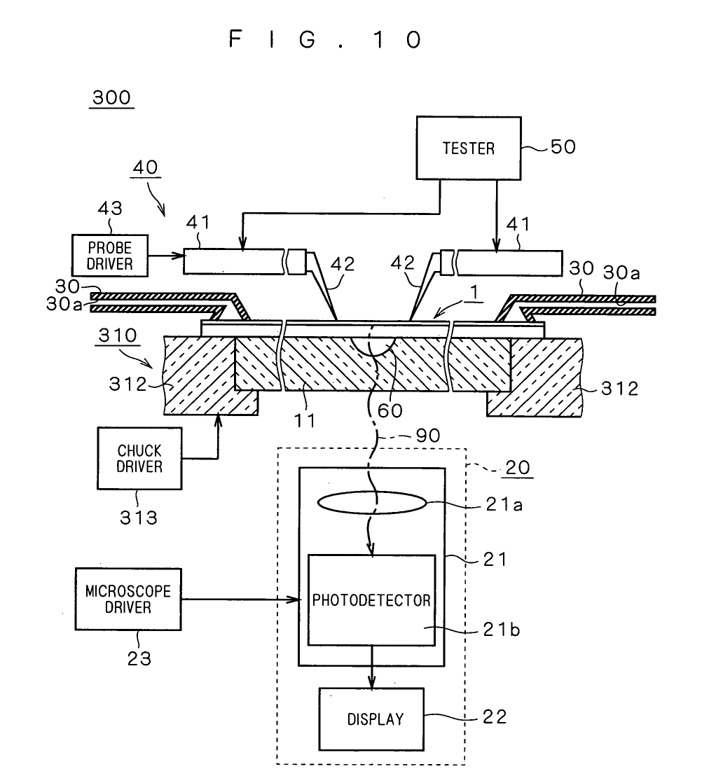

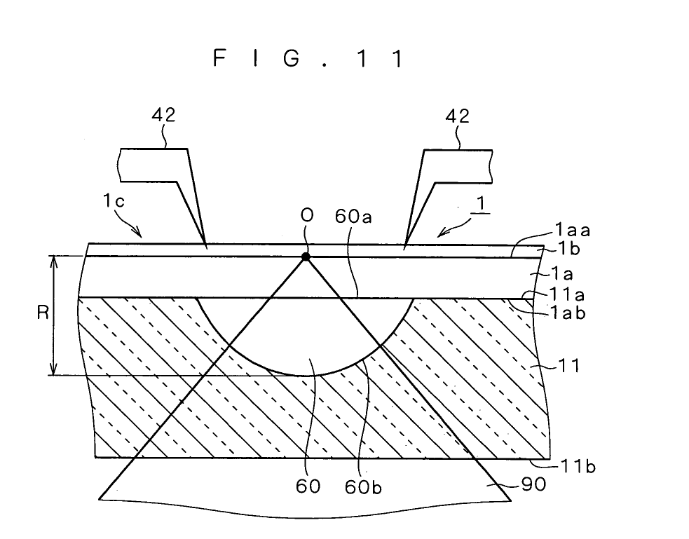

FIG. 10 illustrates a structure of a failure analyzer 300 according to a third preferred embodiment of the present invention. FIG. 11 is a magnified view of a portion of the structure illustrated in FIG. 10. Major structural differences of the failure analyzer 300 according to the third preferred embodiment from the failure analyzer 100 according to the first preferred embodiment lie in that an SIL 60 functioning as a hemispherical SIL is provided in place of the analysis plate 2 and an SIL driver 310 and the stage 11 are provided in place of the SIL driver 10. It is noted that out of the elements illustrated in FIGS. 10 and 11, the sample 1, the SIL 60, the sample support member 30, the stage 11, the probe card 41, and a chuck 312 later described, are illustrated in section.

The SIL 60 is a spherical member obtained by cutting a sphere with one plane and made of silicon, for example. A surface of the SIL 60 includes a flat region 60a and a locally spherical region 60b extending continuously with the flat region 60a. The SIL 60 is embedded in the stage 11 with the locally spherical region 60b facing the main surface 11b of the stage 11 and the flat region 60a being not covered by the stage 11. The flat region 60a of the surface of the SIL 60 is exposed to be flush with the main surface 11a of the stage 11, and both the flat region 60a and the main surface 11a are flat.

The sample 1 is mounted on the main surface 11a of the stage 11 and on the flat region 60a of the SIL 60 with the main surface 1ab of the semiconductor substrate la being situated closer to the stage 11 than the main surface 1aa of the semiconductor substrate 1a. At that time, the SIL 60 and the sample 1 are brought into close contact with each other. Then, a center O of the locally spherical region 60b of the SIL 60 is located on the main surface 1aa of the semiconductor substrate 1a mounted on the stage 11 as illustrated in FIG. 11.

The SIL driver 310 includes the chuck 312 for supporting the stage 11 with the SIL 60 embedded therein by engaging an edge portion of the stage 11, and a chuck driver 313 for moving the chuck 312. The sample 1 is mounted so as to extend over the stage 11, the SIL 60, and the chuck 312.

The chuck driver 313 is capable of moving the chuck 312 in parallel to the main surface 11a of the stage 11 and perpendicularly to the main surface 11a of the stage 111, based on the x,y,z-rectangular coordinate system Q. Thus, the stage 11 and the SIL 60 can be moved in parallel to the main surface 11a of the stage 11 by using the SIL driver 310. Further, the sample support member 30 according to the third preferred embodiment supports the sample 1 independently of the stage 11 and the chuck 312 from above the top surface thereof by vacuum suction. All the other elements included in the structure of the failure analyzer 300 are identical to those of the failure analyzer 100 according to the first preferred embodiment, and thus description thereof is omitted.

Below, a method of carrying out emission analysis on the sample 1 using the failure analyzer 300 according to the third preferred embodiment will be described in detail.

First, the sample 1 is mounted so as to extend over the main surface 11a of the stage 11, the flat region 60a of the SIL 60 embedded in the stage 11, and the chuck 312. At that time, the sample 1 and the stage 11 are brought into close contact with each other. Then, the chuck 312 is moved perpendicularly to the main surface 11a of the stage 11 using the chuck driver 313, to bring the sample 1 and the sample support member 30 into contact with each other. Subsequently, the exhaust hole 30a of the sample support member 30 is evacuated, to draw the sample 1 to the sample support member 30 by suction force. As a result, the sample 1 is held by the sample support member 30 while being in close contact with the SIL 60, and the sample 1 is fixedly positioned.

Subsequently, the chuck 312 is moved using the chuck driver 313, to move the stage 11 along a direction parallel to the main surface 11a thereof. The movement of the chuck 312 is stopped when the SIL 60 is situated just below a predetermined target region for failure analysis of one of the semiconductor chips 1c. Thereafter, the optical microscope 21 is moved to a predetermined position using the microscope driver 23 and a test pattern generated by the tester 50 is applied to the sample 1 in the same manner as in the method described in the first preferred embodiment.

Then, the light 90 which is emitted from a spot of current leakage in the device layer 1b of the one semiconductor chip 1c and penetrates through the SIL 60 and the stage 11 is detected in the optical microscope 21. The optical microscope 21 provides a result of the detection to the display 22. The display 22 receives the result of the detection from the optical microscope 21, and displays the emission position and the emission intensity of the light 90 emitted from the spot of current leakage in the form of an image on a monitor (not illustrated), based on the result of the detection. At that time, also a pattern image of the sample 1 previously stored as data is displayed on the monitor in the display 22. Thus, the pattern image and the emitted light image are displayed while overlapping each other, and a failure caused in the device layer 1b is detected in the failure detector 20. Then, failure analysis of the sample 1 is initiated based on the emitted light image and the pattern image displayed on the monitor of the display 22.

After the failure analysis of the predetermined target region of the one semiconductor chip 1c is finished, the probe card 41 is moved using the probe driver 43, to bring the probe 42 out of contact with the sample 1. Subsequently, the stage 11 is moved along the direction parallel to the main surface 11a thereof such that the SIL 60 is situated just below a different predetermined target region of the same semiconductor chip 1c. Then, failure analysis of the different predetermined target region of the one semiconductor chip 1c is carried out in the same manner as described above. When failure analysis of all regions of the one semiconductor chip 1c is finished, the stage 11 is moved and failure analysis of another one of the semiconductor chips 1c is carried out.

As is made clear from the above description, the failure analyzer 300 according to the third preferred embodiment includes the stage 11 in which the SIL 60 is embedded. The SIL 60 can be moved relative to a target region for analysis in the device layer 1b of the sample 1. Accordingly, an analysis range can be changed, which facilitates failure analysis of an arbitrary region.

Further, since the exposed surface of the SIL 60, i.e., the flat region 60a, is flush with the main surface 11a of the stage 11, and both the flat region 60a and the main surface 11a are flat, it is possible to stably mount the sample 1 on the stage 11 and the SIL 60.

Moreover, according to the third preferred embodiment, the sample 1 is held independently of the stage 11 and the SIL 60 by the sample support member 30. Hence, the sample 1 is not moved even when the stage 11 is moved. Therefore, it is possible to easily align the SIL 60 with a target region for analysis.

Furthermore, according to the third preferred embodiment, since the stage 11 is made of quartz glass, an analysis range can be efficiently searched out even with the SIL 60 being embedded in the stage 11.

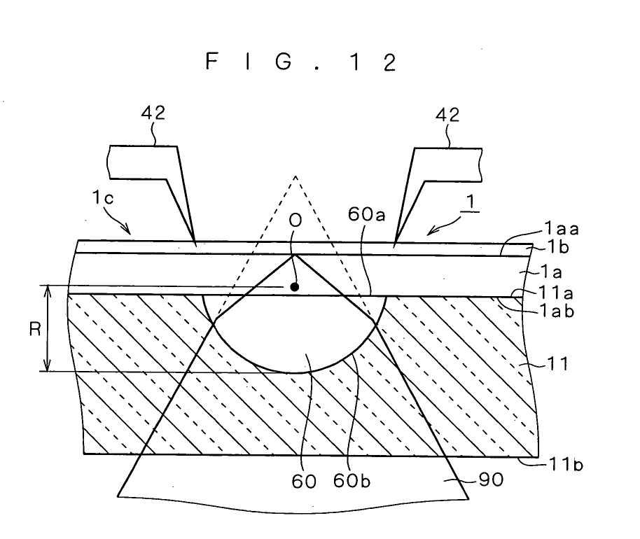

It is noted that though the SIL 60 is formed so as to function as a hemispherical SIL in the above description of the third preferred embodiment, the SIL 60 may alternatively be formed so as to function as a superspherical SIL as illustrated in FIG. 12. In a case where the SIL 60 is formed so as to function as a superspherical SIL, the center 0 of the locally spherical region 60b of the SIL 60 is located within the semiconductor substrate 1a. Assuming that a radius of the locally spherical region 60b of the SIL 60 is “R”, the center O of the locally spherical region 60b is located at a distance of R/n along the thickness of the semiconductor substrate 1a from the main surface 1aa of the semiconductor substrate 1a on the stage 11. On the other hand, the aplanatic point is located on the main surface 1aa of the semiconductor substrate 1a.

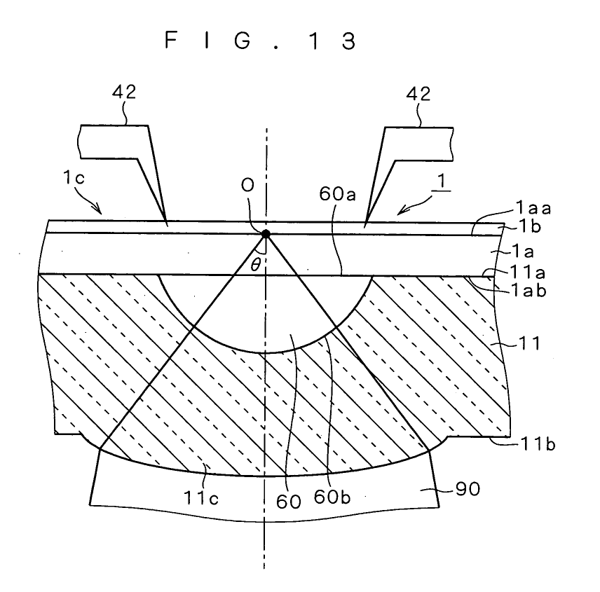

Further, though the main surface 11b of the stage 11 is flat in the structure illustrated in FIG. 10, the main surface 11b of the stage 11 may alternatively be made locally convex by performing some processes on a portion of the main surface 11a as illustrated in FIG. 13. In a structure illustrated in FIG. 13, a protrusion 11c functioning as a convex lens which is aligned with the SIL 60 along the thickness of the stage 11 is formed in the main surface 11b of the stage 11.

In the structure illustrated in FIG. 11, back surface analysis is accomplished by either irradiating a light onto the device layer 1b through the protrusion 11c, the stage 11 and the SIL 60, or detecting a light emitted from the device layer 1b through the SIL 60, the stage 11 and the protrusion 11c.

To additionally include the protrusion 11c functioning as a convex lens in the main surface 11b of the stage 11 as described above could increase the angle θ (a half angle of the converging angle), which provides for further improvement of a resolution.

Fourth Preferred Embodiment

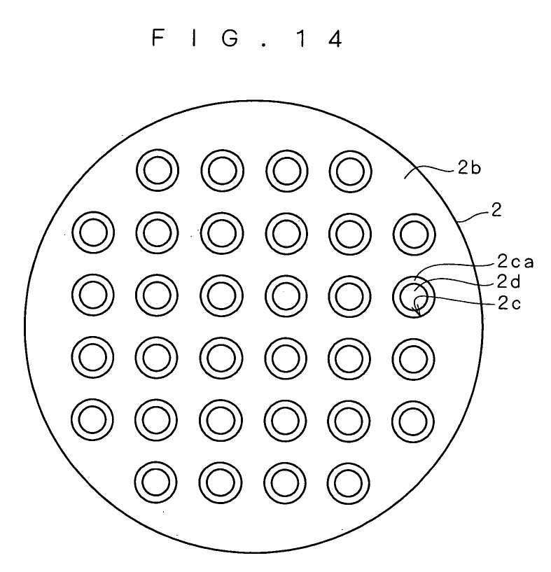

FIG. 14 is a plan view of the analysis plate 2 according to a fourth preferred embodiment of the present invention as it is viewed from above the main surface 2b thereof. According to the fourth preferred embodiment, the analysis plate 2 includes a plurality of recesses 2c provided in the main surface 2b, and a protrusion 2d functioning as an SIL is provided on the bottom surface 2ca of each of the recesses 2c as illustrated in FIG. 14. The plurality of recesses 2c and the plurality of protrusions 2d are situated so as to face the plurality of semiconductor chips 1c of the sample 1, respectively, to be used for analyzing the plurality of semiconductor chips 1c of the sample 1, respectively. Accordingly, when the sample 1 is mounted on the main surface 2a of the analysis plate 2, the plurality of recesses 2c and the plurality of the protrusions 2d are situated below the plurality of semiconductor chips 1c of the sample 1, respectively.

As is made clear from the above description, according to the fourth preferred embodiment, the plurality of recesses 2c and the plurality of protrusions 2d are included in the analysis plate 2. Thus, to employ the analysis plate 2 according to the fourth preferred embodiment in place of the analysis plate 2 according to the first or second preferred embodiment, would reduce a distance of relative movement between the sample 1 and the protrusion 2d, in situating the protrusion 2d just below each of the semiconductor chips 1c on which analysis is to be carried out. As a result, efficiency in failure analysis can be enhanced.

Further, in the analysis plate 2 according to the fourth preferred embodiment, the plurality of recesses 2c and the plurality of protrusions 2d are situated so as to face the plurality of semiconductor chips 1c, respectively, to be used for analyzing the plurality of semiconductor chips 1c, respectively. Thus, to employ the analysis plate 2 according to the fourth preferred embodiment in place of the analysis plate 2 according to the first or second preferred embodiment would require that the sample 1 and the protrusion 2d be moved relative to each other only within an area of one chip. Hence, efficiency in failure analysis can be further enhanced.

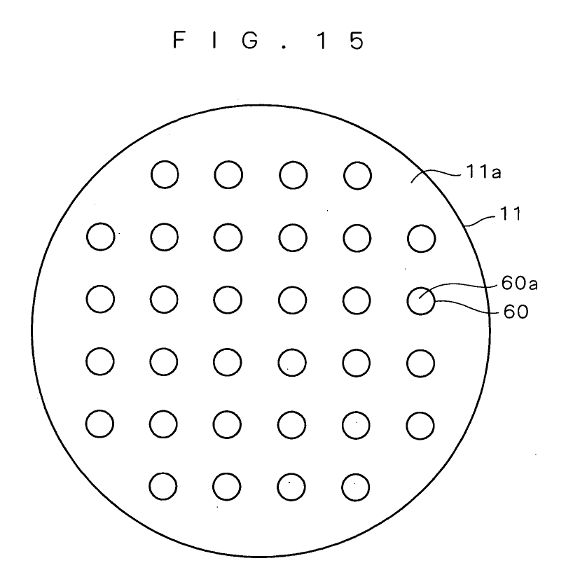

As an alternative to the foregoing structure according to the fourth preferred embodiment in which the plurality of protrusions 2d are included in the analysis plate 2 according to the first or second preferred embodiment, a plurality of SILs 60 may be embedded in the stage 11 according to the third preferred embodiment. FIG. 15 is a plan view of the stage 11 with the plurality of SILs 60 embedded therein as it is viewed from above the main surface 11a. As illustrated in FIG. 15, the plurality of SILs 60 embedded in the stage 11 are situated so as to face the plurality of semiconductor chips 1c, respectively, to be used for analyzing the semiconductor chips, respectively.

To employ the stage 11 with the plurality of SILs 60 embedded therein in place of the stage 11 according to the third preferred embodiment described above would reduce a distance of relative movement between the sample 1 and the SIL 60 in situating the SIL 60 just below each of the semiconductor chips 1c on which analysis is to be carried out. As a result, efficiency in failure analysis can be enhanced.

Further, to employ the stage 11 with the embedded SILs which are situated so as to face the semiconductor chips 1c of the sample 1, respectively, to be used for analyzing the semiconductor chips 1c, respectively, would require that the sample 1 and the SIL 60 be moved relative to each other only within an area of one chip. Hence, efficiency in failure analysis can be further enhanced.

Fifth Preferred Embodiment

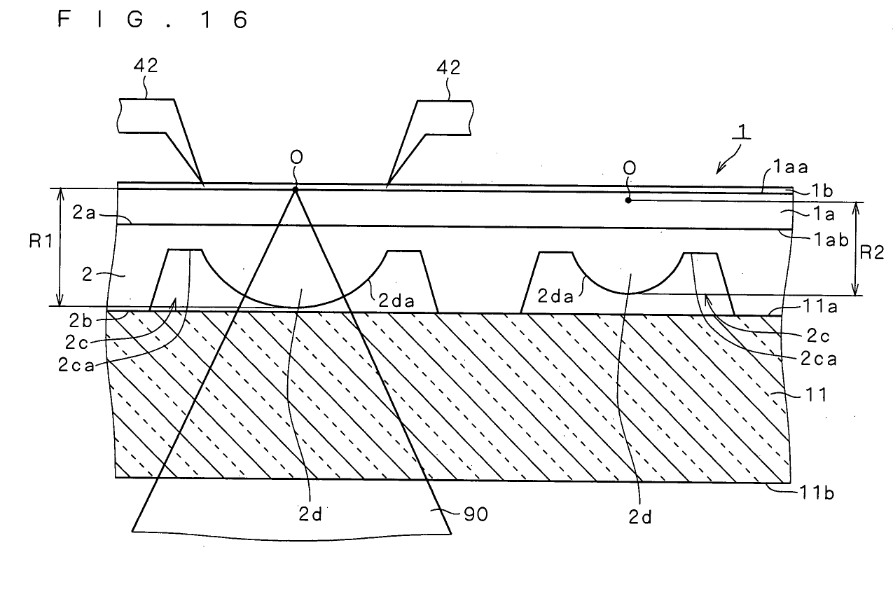

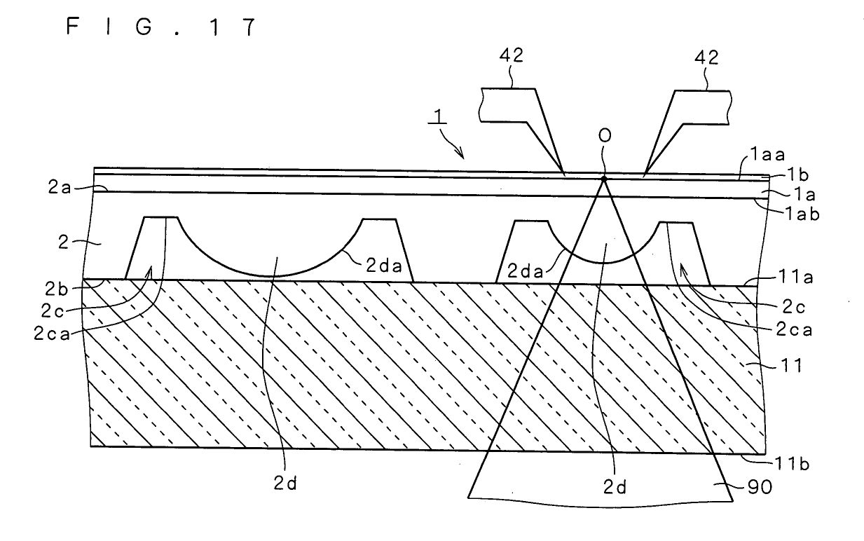

FIGS. 16 and 17 are magnified views of a structure of a portion of a failure analyzer according to a fifth preferred embodiment of the present invention. The failure analyzer according to the fifth preferred embodiment is different from the failure analyzer 100 according to the first preferred embodiment in that a plurality of recesses 2c each including the protrusion 2d provided on the bottom surface 2ca thereof are provided in the main surface 2b of the analysis plate 2, and the respective locally spherical surfaces 2da of the protrusions 2d have different radiuses. It is noted that out of the elements illustrated in FIGS. 16 and 17, the sample 1, the analysis plate 2 and the stage 11 are illustrated in section.

For example, the protrusion 2d including the locally spherical surface 2da with a radius R1 and the protrusion 2d including the locally spherical surface 2da with a radius R2 smaller than the radius R1 are provided on the respective bottom surfaces 2ca of two recesses 2c of the analysis plate 2, as illustrated in FIG. 16.

As described in the above preferred embodiments, an aplanatic point in the sample 1 and the center O of each of the respective locally spherical surfaces 2da of the protrusions 2d are located at the same position in a case where each of the protrusions 2d functions as a hemispherical SIL, while an aplanatic point in the sample 1 is located at a distance of R/n from the center O of each of the respective locally spherical surfaces 2da of the protrusions 2d in a case where each of the protrusions 2d functions as a superspherical SIL. Accordingly, the position of an aplanatic point observed in analysis carrying out using the protrusion 2d including the locally spherical surface 2da with the radius R1 is different from the position of an aplanatic point observed in analysis carrying out using the protrusion 2d including the locally spherical surface 2da with the radius R2.

Thus, when the thickness of the semiconductor substrate 1a of the sample 1 is relatively large, failure analysis of the sample 1 can be achieved by using the protrusion 2d including the locally spherical surface 2da with the radius R1 as illustrated in FIG. 16. On the other hand, when the thickness of the semiconductor substrate 1a of the sample 1 is relatively small, failure analysis of the sample 1 can be achieved by using the protrusion 2d including the locally spherical surface 2da with the radius R2 as illustrated in FIG. 17.

As is made from the above description, the failure analyzer according to the fifth preferred embodiment, the plurality of protrusions 2d including the locally spherical surfaces 2da with different radiuses R are provided in the analysis plate 2. Hence, with only one analysis plate 2, it is possible to analyze a plurality of samples with different thicknesses. This improves an efficiency in analysis.

It is additionally noted that though the above description in the fifth preferred embodiment has been made about a case where the plurality of protrusions 2d including the locally spherical surfaces 2da with different radiuses R are provided in the analysis plate 2 according to the first preferred embodiment, the plurality of protrusions 2d including the locally spherical surfaces 2da with different radiuses R may alternatively be provided in the analysis plate 2 according to the second preferred embodiment. Such alternative structure also produces the same effects as noted above.

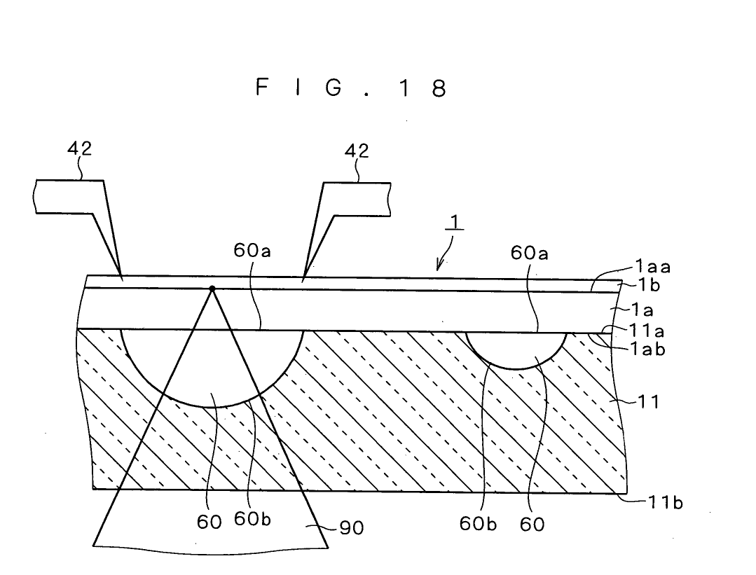

Further alternatively, a plurality of SILs 60 including the locally spherical regions 60b with different radiuses may be embedded in the stage 11 according to the third preferred embodiment, as illustrated in FIG. 18. A structure illustrated in FIG. 18 makes it possible to analyze a plurality of samples with different thicknesses using only one stage 11, to thereby improve efficiency in analysis.

Sixth Preferred Embodiment

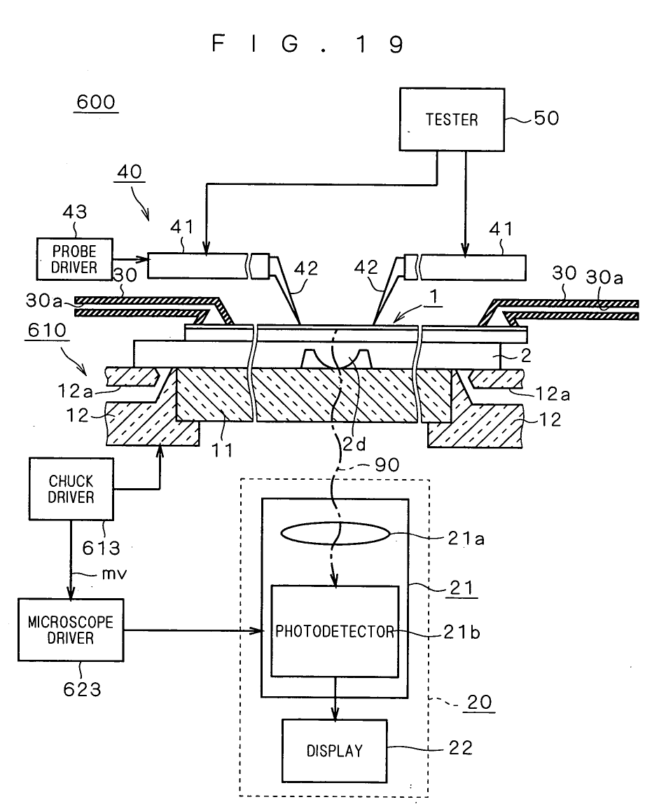

FIG. 19 illustrates a structure of a failure analyzer 600 according to a sixth preferred embodiment of the present invention. The failure analyzer 600 according to the sixth preferred embodiment is structurally different from the failure analyzer 100 according to the first preferred embodiment described above in that an SIL driver 610 and a microscope driver 623 are provided in place of the SIL driver 10 and the microscope driver 23, respectively.

As illustrated in FIG. 19, the SIL driver 610 includes the stage 11 and the chuck 12 which are also included in the failure analyzer 100 according to the first preferred embodiment, and further includes a chuck driver 613. The chuck driver 613 has a function of notifying the microscope driver 623 of information about movement mv of the chuck 12, in addition to functions identical to those of the chuck driver 13 about which have been described in detail in the first preferred embodiment.

In order to change an analysis range, the chuck 12 is moved in parallel to the main surface 11a of the stage 11 as described above in the first preferred embodiment. The chuck driver 613 notifies the microscope driver 623 of information about that movement mv (which will hereinafter be also referred to as “movement information mv”) of the chuck 12. In this regard, since the analysis plate 2 is fixed on the stage 11 and the stage 11 is supported by the chuck 12 as described above, the movement information mv notified by the chuck driver 613 can be employed as not only the movement information of the chuck 12, but also movement information of the analysis plate 2. It is additionally noted that the movement information mv is indicated by a value of an x coordinate and a value of a y coordinate in the above described x,y,z-rectangular coordinate system Q, for example.

Upon receipt of the movement information mv from the chuck driver 613, the microscope driver 623 moves the optical microscope 21 in parallel to the main surface 2a of the analysis plate 2 based on the received movement information mv, to situate the optical system 21a just below the protrusion 2d.

As is made clear from the above description, in the failure analyzer 600 according to the sixth preferred embodiment, the chuck driver 613 functions to notify the microscope driver 623 of movement information mv which includes information about movements of the chuck 12 and the analysis plate 2, and the microscope driver 623 moves the optical microscope 21 based on the received movement information mv. Accordingly, it is possible to automatically move the optical system 21a and the photodetector 21b to appropriate positions in accordance with the movement of the analysis plate 2. As a result, an analysis range can be more efficiently changed, to thereby shorten a period of time required for analysis.

It is noted that the above-described structure according to the sixth preferred embodiment is based on the structure according to the first preferred embodiment, where an additional function of notifying the microscope driver 23 of the movement information mv of the chuck 12 and an additional function of moving the optical microscope 21 based on the movement information mv received from the chuck driver 13 are imparted respectively to the chuck driver 13 and the microscope driver 23. Alternatively, the same additional functions as noted above may be imparted respectively to the chuck driver 13 and the microscope driver 23 in the structure according to the fifth preferred embodiment. Further alternatively, an additional function of notifying the microscope driver 23 of movement information mv of the chuck 212 and an additional function of moving the optical microscope 21 based on the movement information mv received from the chuck driver 213 are imparted respectively to the chuck driver 213 and the microscope driver 23 according to the second preferred embodiment. Those alternative embodiments also produce the same effects as described above.

Even further alternatively, an additional function of notifying the microscope driver 23 of movement information mv of the chuck 312 and an additional function of moving the optical microscope 21 based on the movement information mv received from the chuck driver 313 are imparted respectively to the chuck driver 313 and the microscope driver 23 in the structure according to the third preferred embodiment. In this alternative embodiment, it is possible to automatically move the optical system 21a and the photodetector 21b to appropriate positions in accordance with movement of the SIL 60. As a result, an analysis range can be more efficiently changed, to thereby shorten a period of time required for analysis.

Moreover, by employing the analysis plate 2 in the structure illustrated in FIG. 14 according to the fourth preferred embodiment in place of the analysis plate 2 in the structure illustrated in FIG. 19, also the same effects as described in the fourth preferred embodiment can be produced.

Seventh Preferred Embodiment

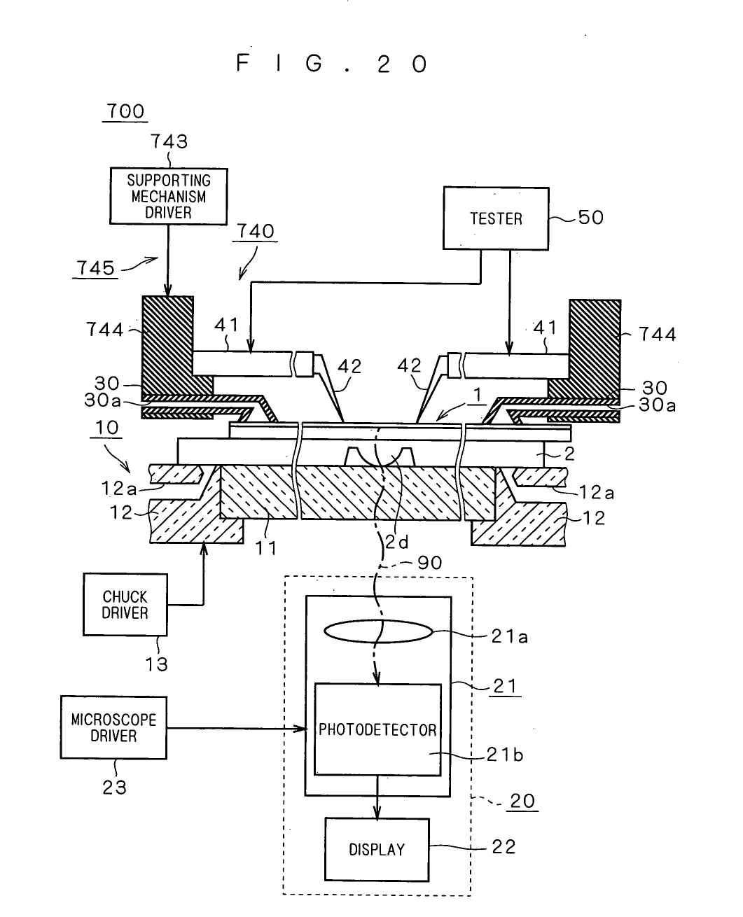

FIG. 20 illustrates a structure of a failure analyzer 700 according to a seventh preferred embodiment of the present invention. The failure analyzer 700 according to the seventh preferred embodiment is structurally different from the failure analyzer 100 according to the first preferred embodiment in that a prober 740 including the sample support member 30 is provided in place of the prober 40.

The prober 740 includes the probe card 41 and the probe 42 which are also included in the failure analyzer 100 according to the first preferred embodiment, and further includes a probe/sample driver 745. The probe/sample driver 745 includes a supporting mechanism driver 743, a supporting mechanism 744 and the sample support member 30 which is also included in the failure analyzer 100 according to the first preferred embodiment.

In the failure analyzer 100 according to the first preferred embodiment, the sample support member 30 is attached to the housing which contains the stage 11 and the like as described above. In contrast thereto, the sample support member 30 is attached to the supporting mechanism 744 in the failure analyzer 700 according to the seventh preferred embodiment. Also the probe card 41 is attached to the supporting mechanism 744 in the failure analyzer 700.

The supporting mechanism driver 743 is capable of moving the supporting mechanism 744 in parallel to the main surface 2a of the analysis plate 2 and perpendicularly to the main surface 2a of the analysis plate 2 based on the x,y,z-rectangular coordinate system Q.

As described above, the sample support member 30 and the probe card 41 are attached to the supporting mechanism 744. Also, the sample 1 is supported by the sample support member 30 and the probe 42 is connected to the probe card 41. Accordingly, to move the supporting mechanism 744 with the sample 1 being supported by the sample support member 30 would result in movement of the probe 42 and the sample 1 without involving change in positional relationship therebetween.

As is made clear from the above description, it is possible to move the sample 1 and the probe 42 in parallel to, and perpendicularly to, the main surface 2a of the analysis plate 2 without involving change in positional relationship therebetween by employing the probe/sample driver 745. All the other elements included in the failure analyzer 700 are identical to those included in the failure analyzer 100 according to the first preferred embodiment, and thus detailed description thereof is omitted herein.

Below, a method of carrying out emission analysis on the sample 1 using the failure analyzer 700 according to the seventh preferred embodiment will be described in detail.

First, the sample 1 is mounted on the analysis plate 2 fixed on the stage 11 in the same manner as described in the first preferred embodiment. Then, the chuck 12 is moved perpendicularly to the main surface 11a of the stage 11 using the chuck driver 13, to bring the sample 1 and the sample support member 30 into contact with each other. Subsequently, vacuum suction is caused to draw the sample 1 to the sample support member 30. At that time, the probe 42 comes into contact with an electrode pad provided in the device layer 1 b of the sample 1.

Next, the supporting mechanism 744 is moved in parallel to the main surface 2a of the analysis plate 2 using the supporting mechanism driver 743 with the sample 1 and the analysis plate 2 being in close contact with each other. The supporting mechanism 744 is moved until a predetermined target region for analysis of one of the semiconductor chips 1c is situated above the protrusion 2d. During the movement of the supporting mechanism 744, the sample 1 and the probe 42 are moved without involving change in positional relationship therebetween. After the movement of the supporting mechanism 744 is stopped, the optical microscope 21 is moved to a predetermined position using the microscope driver 23, and a test pattern generated by the tester 50 is applied to the sample 1 via the probe 42.

Thereafter, the light 90 which is emitted from a spot of current leakage in the device layer 1b of the one semiconductor chip 1c and penetrates through the protrusion 2d of the analysis plate 2 and the stage 11 is detected in the optical microscope 21, and failure analysis is initiated.

After failure analysis of the predetermined target region of the one semiconductor chip 1c is finished, the supporting mechanism 744 is moved in parallel to the main surface 2a of the analysis plate 2 using the supporting mechanism driver 743, to move the sample 1 so that the protrusion 2d is situated below a different target region for analysis of the same semiconductor chip 1c. During the movement of the supporting mechanism 744, also the probe 42 is moved with maintaining positional relationship between the probe 42 and the sample 1. Then, failure analysis of the different target region for analysis is carried out in the same manner as described above.

As is made clear from the above description, the probe 42 and the sample 1 can be moved without involving change in positional relationship therebetween in the failure analyzer 700 according to the seventh preferred embodiment. Accordingly, there is no need of moving the analysis plate 2 and the optical system 21a in changing an analysis range. This provides for improvement of an efficiency in analysis.

It is additionally noted that though above description of the seventh preferred embodiment has been made about a case where the prober 740 including the sample support member 30 is used in place of the prober 40 according to the first preferred embodiment, the prober 740 including the sample support member 30 may be used in place of the prober 40 according to the second, third or fifth preferred embodiment. The same effects as noted above can be produced also in using the prober 740 in the second, third or fifth preferred embodiment.

Further, to employ the analysis plate 2 in the structure illustrated in FIG. 14 according to the fourth preferred embodiment in place of the analysis plate 2 in the structure illustrated in FIG. 20 would produce the same effects as described in the fourth preferred embodiment.

While the invention has been shown and described in detail, the foregoing description is in all aspects illustrative and not restrictive. It is therefore understood that numerous modifications and variations can be devised without departing from the scope of the invention.

Claimed is:

1. A failure analyzer comprising:
an analysis plate including a first main surface mounting a sample thereon and a second main surface opposite to said first main surface; and
a failure detector including an optical system and detecting a failure caused in said sample using said optical system, wherein
a recess is provided in said second main surface of said analysis plate,
a protrusion which functions as a solid immersion lens and does not protrude from said second main surface is provided on a bottom surface of said recess, and
said failure detector irradiates a light onto said sample through said protrusion from a direction of said second main surface of said analysis plate, or detects a light which is emitted from said sample and penetrates through said protrusion.

2. The failure analyzer according to claim 1, wherein, said analysis plate is also used as a stage mounting said sample thereon.

3. The failure analyzer according to claim 1, wherein said analysis plate is made of silicon.

4. The failure analyzer according to claim 2, wherein, said analysis plate is made of quartz glass.

5. The failure analyzer according to claim 1, wherein said recess provided in said second main surface of said analysis plate includes a plurality of recesses, and
said protrusion includes a plurality of protrusions provided on respective bottom surfaces of said plurality of recesses.

6. The failure analyzer according to claim 5, wherein
said sample includes a semiconductor wafer in which a plurality of semiconductor chips are formed, and
said plurality of recesses and said plurality of protrusions are situated so as to face said plurality of semiconductor chips, respectively, to be used for analyzing said plurality of semiconductor chips, respectively.

7. The failure analyzer according to claim 5, wherein
each of said plurality of protrusions is spherical, and
said plurality of protrusions include respective locally spherical surfaces with different radiuses.

8. The failure analyzer according to claim 1, further comprising:
a support member for supporting said sample independently of said analysis plate; and
a first driver for moving said analysis plate in parallel to said first main surface.

9. The failure analyzer according to claim 8, further comprising
a second driver for moving said optical system of said failure detector in parallel to said first main surface of said analysis plate, wherein
said first driver notifies said second driver of movement information of said analysis plate, and
said second driver moves said optical system based on said movement information.

10. The failure analyzer according to claim 1, further comprising:
a probe coming into contact with said sample on said analysis plate; and
a driver for moving said probe and said sample in parallel to said first main surface of said analysis plate independently of said analysis plate without involving change in positional relationship between said probe and said sample.

11. A failure analyzer comprising:
a solid immersion lens;
a stage including a first main surface and a second main surface opposite to said first main surface, said solid immersion lens being embedded in said stage; and
a failure detector including an optical system and detecting a failure caused in a sample using said optical system, wherein
a portion of a surface of said solid immersion lens is flat and is exposed to be flush with said first main surface of said stage,
said sample is mounted so as to extend over said first main surface of said stage and said portion of said surface of said solid immersion lens, and
said failure detector irradiates a light onto said sample through said stage and said solid immersion lens from a direction of said second main surface of said stage, or detects a light which is emitted from said sample and penetrates through said solid immersion lens and said stage.

12. The failure analyzer according to claim 11, wherein
said stage is made of quartz glass.

13. The failure analyzer according to claim 11, wherein
a protrusion functioning as a convex lens is provided in said second main surface of said stage, said protrusion being aligned with said solid immersion lens along a thickness of said stage, and
said light irradiated by said failure detector onto said sample penetrates through said protrusion, said stage and said solid immersion lens, or said light which is emitted from said sample and is detected by said failure detector penetrates through said solid immersion lens, said stage and said protrusion.

14. The failure analyzer according to claim 11, wherein
said solid immersion lens embedded in said stage includes a plurality of solid immersion lenses.

15. The failure analyzer according to claim 14, wherein
said sample includes a semiconductor wafer in which a plurality of semiconductor chips are provided, and
said plurality of solid immersion lenses are situated so as to face said plurality of semiconductor chips, respectively, to be used for analyzing said plurality of semiconductor chips, respectively.

16. The failure analyzer according to claim 14,
each of said plurality of solid immersion lenses is spherical, and
said plurality of solid immersion lenses include respective locally spherical surfaces with different radiuses.

17. The failure analyzer according to claim 11, further comprising:
a support member for supporting said sample independently of said stage and said solid immersion lens; and
a first driver for moving said stage in parallel to said first main surface of said stage.

18. The failure analyzer according to claim 17, further comprising
a second driver for moving said optical system of said failure detector in parallel to said first main surface of said stage, wherein
said first driver notifies said second driver of movement information of said stage, and
said second driver moves said optical system based on said movement information.

19. The failure analyzer according to claim 11, further comprising:
a probe coming into contact with said sample on said stage and said solid immersion lens; and
a driver for moving said probe and said sample in parallel to said first main surface of said stage independently of said stage without involving change in positional relationship between said probe and said sample.
